(19) United States
(12) Patent Application Publication
(10) Pub. No.: US 2025/0349564 A1
(43) Pub. Date: Nov. 13, 2025

(54) SUBSTRATE PROCESSING APPARATUS AND SUBSTRATE PROCESSING METHOD

(71) Applicant: SEMES CO., LTD., Cheonan-si (KR)

(72) Inventor: Jun Young CHOI, Cheongju-si (KR)

(73) Assignee: SEMES CO., LTD., Cheonan-si (KR)

(21) Appl. No.: 19/203,779

(22) Filed: May 9, 2025

(30) Foreign Application Priority Data
May 10, 2024 (KR) 10-2024-0061962

(51) Int. Cl. H01L 21/67; H01L 21/687; H05B 6/10

(52) U.S. Cl. CPC H01L 21/67051; H01L 21/67248; H01L 21/68764; H01L 21/68785; H05B 6/109

(57) ABSTRACT

The substrate processing apparatus includes a housing for providing a treatment space to treat a substrate; a support unit positioned in the treatment space and for supporting the substrate; a nozzle for supplying a treatment solution to the substrate supported on the support unit; and a heating unit for heating an edge region of the substrate supported on the support unit, in which the support unit includes a support plate on which the substrate is placed; a pin for supporting the substrate placed on the support plate; and a drive unit for rotating the support plate, and the heating unit includes an insertion body made of metal located within the chuck pin; and a magnet unit for heating the insertion body by an induction heating manner.

### CROSS-REFERENCE TO RELATED APPLICATIONS

This application claims priority to and the benefit of Korean Patent Application No. 10-2024-0061962 filed in the Korean Intellectual Prope Office on May 10, 2024, the entire contents of which are incorporated herein by reference.

### TECHNICAL FIELD

The present invention relates to a substrate processing method and a substrate processing apparatus, and more particularly to a substrate processing apparatus of processing a substrate at a uniform temperature.

### BACKGROUND ART

A semiconductor process includes a process of cleaning a thin film, foreign substances, particles, and the like on a substrate. These processes are achieved by placing a substrate on a spin chuck with the patterned surface facing up or down, applying a treatment solution to the substrate while the spin chuck is rotated, and subsequently drying a wafer.

When treating the substrate with the treatment solution, the substrate may be treated at a high temperature by supplying the treatment solution heated to a high temperature onto the substrate, or by heating the substrate to a high temperature. In the case of high-temperature processes, it is necessary to maintain a uniform temperature of the substrate because the reactivity of the treatment solution varies depending on the temperature of the treatment solution.

However, in general, when a substrate is rotated, the temperature of the treatment solution present in the edge region drops more easily because the velocity at the edge region is higher than the velocity at the center of the substrate. Furthermore, even if a heater is installed in the support unit, it may not be provided to the extent that the front surface of the substrate can be heated. As a result, there is a problem in that the temperature uniformity of the treatment solution is not maintained and the substrate is treated unevenly.

### SUMMARY OF THE INVENTION

The present invention has been made in an effort to provide a substrate processing apparatus and a substrate processing method capable of treating a substrate at a uniform temperature when treating the substrate with a high temperature treatment solution.

The present invention has also been made in an effort to provide a substrate processing apparatus and a substrate processing method capable of inductively heating an edge region of a substrate.

The objectives of the present disclosure are not limited thereto and other objectives not stated herein may be clearly understood by those skilled in the art from the following description.

An exemplary embodiment of the present invention, an apparatus of processing a substrate, the apparatus comprising: a housing for providing a treatment space to treat a substrate; a support unit positioned in the treatment space and for supporting the substrate; a nozzle for supplying a treatment solution to the substrate supported on the support unit; and a heating unit for heating an edge region of the substrate supported on the support unit, wherein the support unit includes: a support plate on which the substrate is placed; a pin for supporting the substrate placed on the support plate; and a drive unit for rotating the support plate, and the heating unit may include: an insertion body made of metal located within the chuck pin; and a magnet unit for heating the insertion body by an induction heating manner.

According to the exemplary embodiment of the present invention, the pin may be a chuck pin that supports a side portion of the substrate placed on the support plate.

According to the exemplary embodiment of the present invention, the magnet unit is located at a lower portion of the chuck pin and may provide to be spaced apart from the support plate.

According to the exemplary embodiment of the present invention, the support unit includes a frame surrounding the drive unit, the frame is provided to be fixed in position with respect to rotation of the support unit, and the magnet unit may be installed on the frame.

According to the exemplary embodiment of the present invention, the support unit includes a frame surrounding the drive unit, the frame is provided with a cleaning unit for cleaning a lower portion of the support plate, the magnet unit includes a plurality of magnets, and the plurality of magnets may be installed in the cleaning unit.

According to the exemplary embodiment of the present invention, the magnet unit includes a plurality of magnets, and the plurality of magnets may be disposed while being spaced apart from each other along a circumferential direction of the support plate.

According to the exemplary embodiment of the present invention, each of the plurality of magnets may be provided with a top end and a bottom end having different polarities, and the top ends of adjacent magnets of the plurality of magnets have different polarities.

According to the exemplary embodiment of the present invention, the apparatus may further include a controller for controlling the drive unit, wherein the controller controls a rotation speed of the support plate according to a set temperature for treating the substrate.

According to the exemplary embodiment of the present invention, the support unit may include: an electromagnet; a power source for providing the electromagnet with power. According to the exemplary embodiment of the present invention, the apparatus may further include a controller for controlling the power source, wherein the controller controls the power source so that set power is applied to the electromagnet according to a set temperature for treating the substrate.

According to the exemplary embodiment of the present invention, the insertion body has a plate shape, and the insertion bodies may provide in plurality to be stacked on top of each other.

According to the exemplary embodiment of the present invention, the support unit may include a heater for heating the substrate supported by the support plate.

An exemplary embodiment of the present invention, a method of processing a substrate by using a substrate processing apparatus, the method comprising: the substrate processing apparatus includes: a housing for providing a treatment space to treat a substrate; a support unit positioned in the treatment space and supporting the substrate; a nozzle for supplying a treatment solution to the substrate supported on the support unit; and a heating unit for heating an edge region of the substrate supported on the support unit, the support unit includes: a support plate on which the substrate is placed; a chuck pin for supporting a side portion of the substrate placed on the support plate; and a drive unit for rotating the support plate, and the heating unit includes: an insertion body made of metal located within the chuck pin; and a magnet unit for heating the insertion body by an induction heating manner, and the method includes supplying a treatment solution to the rotated substrate, and inductively heating the insertion body with the heating unit to heat an edge region of the substrate.

According to the exemplary embodiment of the present invention, the treatment solution may be supplied to the substrate in a heated state.

According to the exemplary embodiment of the present invention, the support unit may include a heater for heating the substrate supported by the support plate, and the heater heats the substrate.

According to the exemplary embodiment of the present invention, the chuck pin includes: a first chuck pin; and a second chuck pin provided with an insertion body having a thickness different from a thickness of the insertion body provided in the first chuck pin, and the method may include treating the substrate by installing the chuck pin selected from the first chuck pin and the second chuck pin on the support plate according to a set temperature for treating the substrate.

According to the exemplary embodiment of the present invention, a rotational speed of the support unit may be changed according to a set temperature for treating the substrate.

According to the exemplary embodiment of the present invention, the magnet unit includes an electromagnet, and a power source for supplying the electromagnet with power, and the method may include varying the power supplied to the electromagnet according to a set temperature for treating the substrate.

An exemplary embodiment of the present invention, an apparatus of processing a substrate, the apparatus comprising: a housing for providing a treatment space to treat a substrate; a support unit positioned in the treatment space and supporting the substrate; a nozzle for supplying a treatment solution to the substrate supported on the support unit; and a heating unit for heating an edge region of the substrate supported on the support unit, wherein the support unit includes: a support plate on which the substrate is placed; a chuck pin for supporting a side portion of the substrate placed on the support plate; and a drive unit for rotating the support plate; and a heater for heating the substrate supported by the support plate, the heating unit includes: an insertion body made of metal located within the chuck pin; and a magnet unit located at a lower portion of the pin, and provided to be spaced apart from the support plate, the support unit further includes a frame surrounding the drive unit, the magnet unit includes a plurality of magnets, the plurality of magnets is spaced apart from each other along a circumferential direction of the support plate, any one of the plurality of magnets has a different polarity from another magnet of the plurality of magnets, and the plurality of magnets of different polarities may be provided to be adjacent to each other.

According to the exemplary embodiment of the present invention, the support unit further includes: an electromagnet; and a power source for supplying power to the electromagnet, the apparatus further includes a controller for controlling the power source, and the controller may control the power source according to a temperature for treating the substrate or a speed for rotating the substrate.

According to the exemplary embodiment of the present invention, uniformity may be improved when treating a substrate with high temperatures.

According to the exemplary embodiment of the present invention, the edge regions of the substrate may be inductively heated.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating a liquid treating chamber of FIG. 1 according to the exemplary embodiment.

FIG. 3 is a schematic diagram illustrating a heater added to a liquid treating chamber of FIG. 2.

FIG. 4 is a cross-sectional view illustrating a cross-section of a chuck pin of FIG. 2.

FIG. 5 is a diagram schematically illustrating another exemplary embodiment of the chuck pin of FIG. 4.

FIG. 6 is a diagram schematically illustrating the use of an electromagnet in the liquid treating chamber of FIG. 2.

FIG. 7 is a diagram schematically illustrating the use of a lifting unit in the liquid treating chamber of FIG. 2.

FIG. 8 is a diagram schematically illustrating the use of a cleaning unit in the liquid treating chamber of FIG. 2.

### DETAILED DESCRIPTION

Hereinafter, an exemplary embodiment of the present invention will be described in more detail with reference to the accompanying drawings. The exemplary embodiment of the present invention may be modified in various forms, and the scope of the present invention should not be construed as being limited to the following exemplary embodiments. This exemplary embodiment is provided to more completely explain the present invention to those of ordinary skill in the art. Therefore, the shapes of elements in the drawings are exaggerated to emphasize a clearer description.

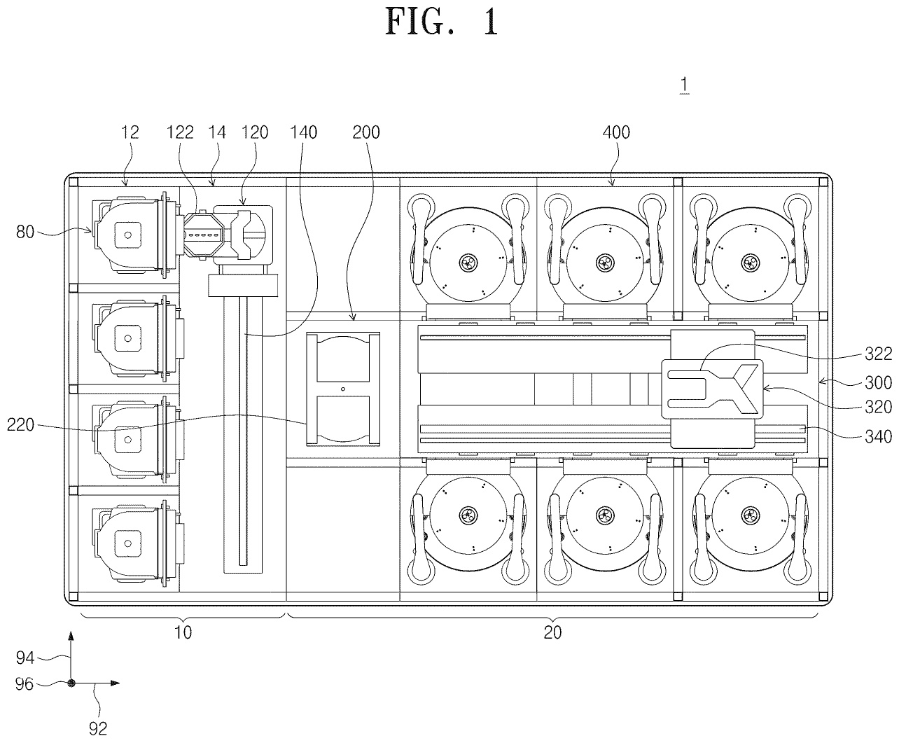

FIG. 1 is a top plan view schematically illustrating a substrate processing apparatus according to an exemplary embodiment of the present invention.

Referring to FIG. 1, a substrate processing apparatus includes an index module 10, a treating module 20, and a controller 30. In the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the vertical direction, and is capable of independently moving forward and backward.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

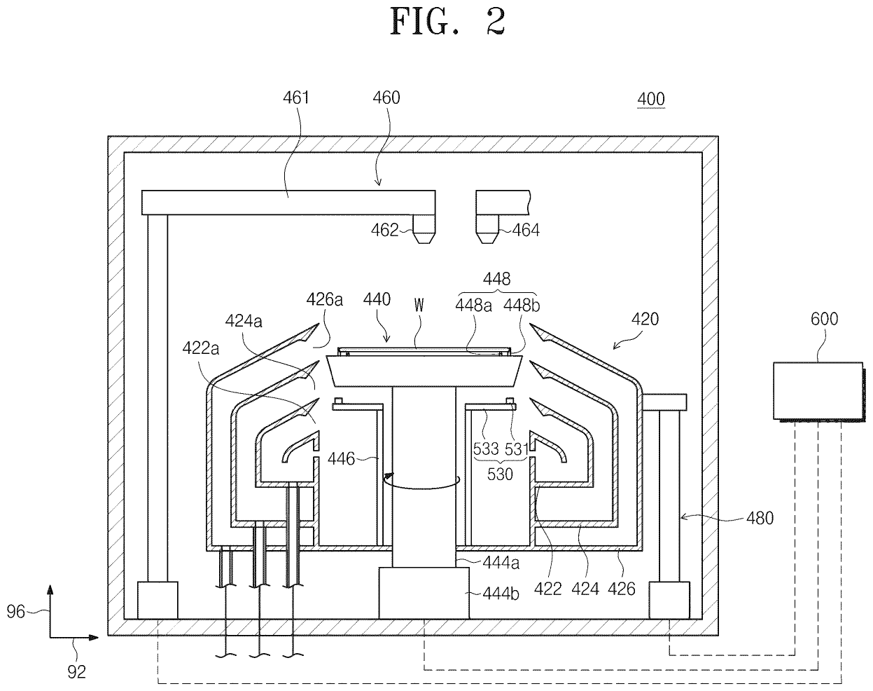

FIG. 2 is a diagram schematically illustrating the exemplary embodiment of the liquid treating chamber 400 of FIG. 1. Referring to FIG. 2, the liquid treating chamber 400 includes a housing 410, a cup 420, a support unit 440, a nozzle unit 460, a lifting unit 480, a heating unit 500, and a controller 600.

The housing 410 is provided in a generally rectangular parallelepiped shape. The cup 420, the support unit 440, and the nozzle unit 460 are disposed within the housing 410.

The cup 420 has a treatment space with an open top, and the substrate W is liquid-treated in the treatment space. The support unit 440 supports the substrate W in the treatment space. The nozzle unit 460 supplies a liquid onto the substrate W supported on the support unit 440. The liquid may be provided in a plurality of types, and may be sequentially supplied onto the substrate W. The lifting unit 480 adjusts a relative height between the cup 420 and the support unit 440.

According to the example, the cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. As the liquid treatment process proceeds, the treatment solution scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442, a drive unit 444, a frame 446, and a pin 448. An upper surface of the support plate 442 may be provided in a generally circular shape, and may have a diameter larger than a diameter of the substrate W. The drive unit 444 includes a drive shaft 444a and a driver 444b. The drive shaft 444a is coupled to the center of the lower surface of the support plate 442. Further, the drive shaft 444a is provided with a driver 444b to provide rotational force. The driver 444b rotates the drive shaft 444a. Accordingly, the support plate 442 is rotated about the axis of the drive shaft 444a. In one example, the driver 444b may be a motor. The frame 446 is provided to surround the drive shaft 444a. The frame 446 may be provided to be independent of the rotation of the drive shaft 444a. Accordingly, the frame 446 may remain stationary even when the support plate 442 is rotated by the drive unit 444. The frame 446 may be coupled to a magnet unit 530, which will be described later. The pin 448 includes a support pin 448a and a chuck pin 448b. The support pin 448a supports the rear surface of substrate W. The support pin 448a is provided on the top surface of the support plate 442. The support pin 448a is provided inwardly of the chuck pin 448b. The support pin 448a is provided with a top end protruding from the support plate 442 such that the substrate W is spaced a certain distance from the support plate 442. The chuck pin 442b supports the side portion of the substrate W so that the substrate W is not separated from the support unit 440 when the substrate W is rotated. The chuck pin 448b may be removably provided from the support plate 442. An insertion body 510, to be described later, may be provided within the chuck pin 448b. More details regarding the chuck pin 448b will be discussed later.

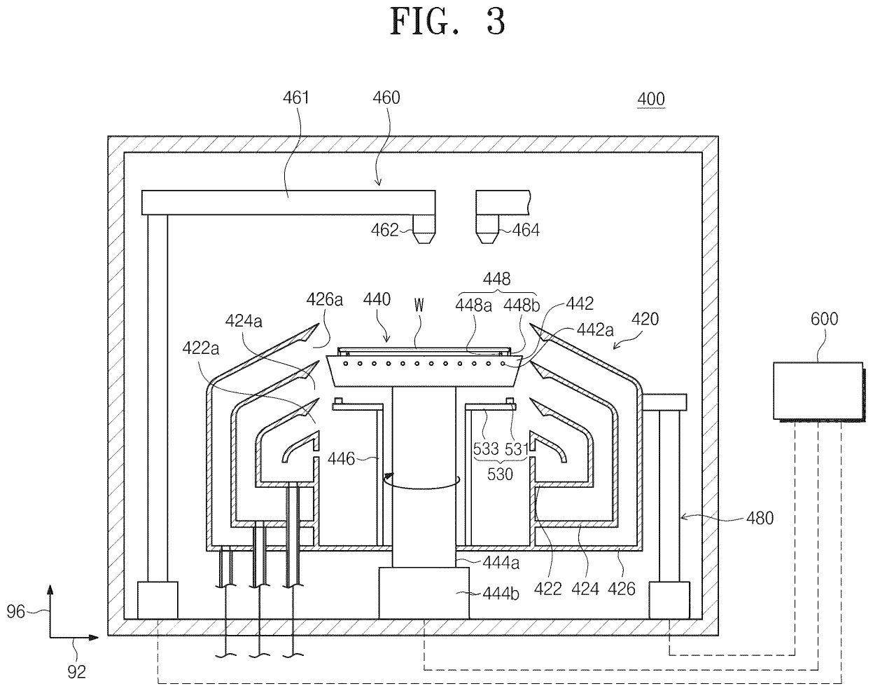

In the example described above, the present invention has been described based on the case where no means for heating the substrate W is provided. However, without limitation, the support plate 442 may be provided with a heater 442a for heating the substrate W, as illustrated in FIG. 3. The heater 442a may be a heating plate or a heating wire. However, it is not limited thereto, but any means capable of heating the substrate W will suffice. Accordingly, the substrate W may be heated at the same time as the treatment solution is supplied at a high temperature, or the substrate W may be supplied with a low temperature treatment solution and the substrate W heated.

The nozzle unit 460 includes a first nozzle 462 and a second nozzle 464. The first nozzle 462 supplies the treatment solution onto the substrate W. The treatment solution may be a liquid having a temperature higher than room temperature. According to an example, the treatment solution may be an aqueous phosphoric acid solution. The aqueous phosphoric acid solution may be a mixture of phosphoric acid and water. Optionally, the aqueous phosphoric acid solution may further contain other substances. For example, the other material may be silicon. The second nozzle 464 supplies water onto the substrate W. The water may be pure water or deionized water.

The first nozzle 462 and the second nozzle 464 are each supported on different arms 461, and the arms 461 may be moved independently. Optionally, the first nozzle 462 and the second nozzle 464 may be mounted on the same arm and moved at the same time.

Optionally, the liquid supply unit may further include one or more nozzles in addition to the first nozzle 462 and the second nozzle 464. Additional nozzles may supply different types of treatment solutions to the substrate. For example, the other type of treatment solution may be an acid solution or a base solution for removing foreign substances on the substrate. In addition, another type of treatment solution may be alcohol having surface tension lower than that of water. For example, the alcohol may be isopropyl alcohol.

The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment solution are changed according to the type of liquid supplied to the substrate W, and thus the liquids may be separated and recovered. Unlike the description, the cup 420 may be fixedly installed, and the lifting unit 480 may move the support unit 440 in the vertical direction. In one example, the lifting unit 480 may include a motor (not illustrated).

The heating unit 500 heats an edge region of the substrate W. The heating unit 500 includes an insertion body 510 and a magnet unit 530. The insertion body 510 may be provided within the chuck pin 448b.

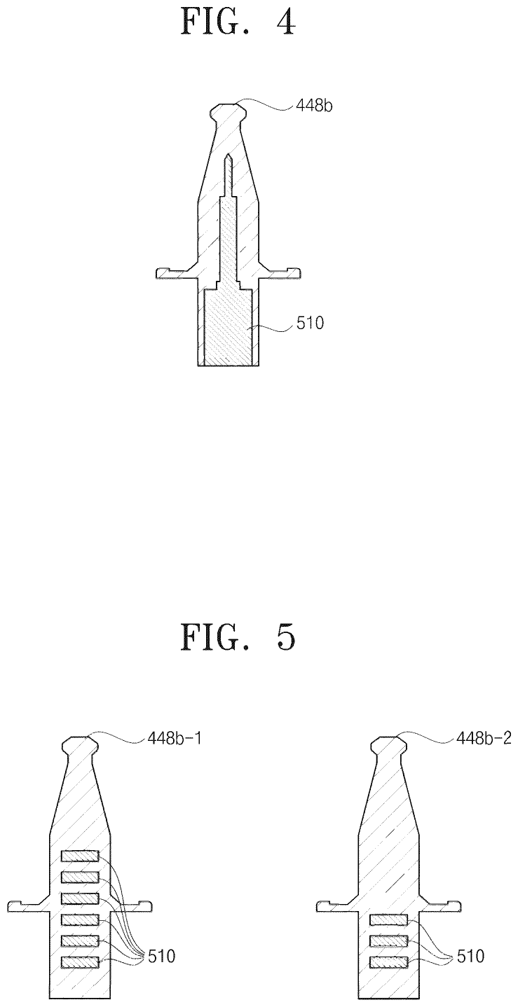

FIG. 4 is a diagram illustrating a cross-section of the chuck pin of FIG. 2 according to the exemplary embodiment. Referring to FIG. 4, the chuck pin 448b may be provided with the insertion body 510 inside. The insertion body 510 may be provided of a metallic material. The insertion body 510 may be provided in the shape of a plate. Further, the insertion body 510 may be provided in a plurality and may be stacked on top of each other. The insertion body 510 may be inductively heated by a heating unit to be described later.

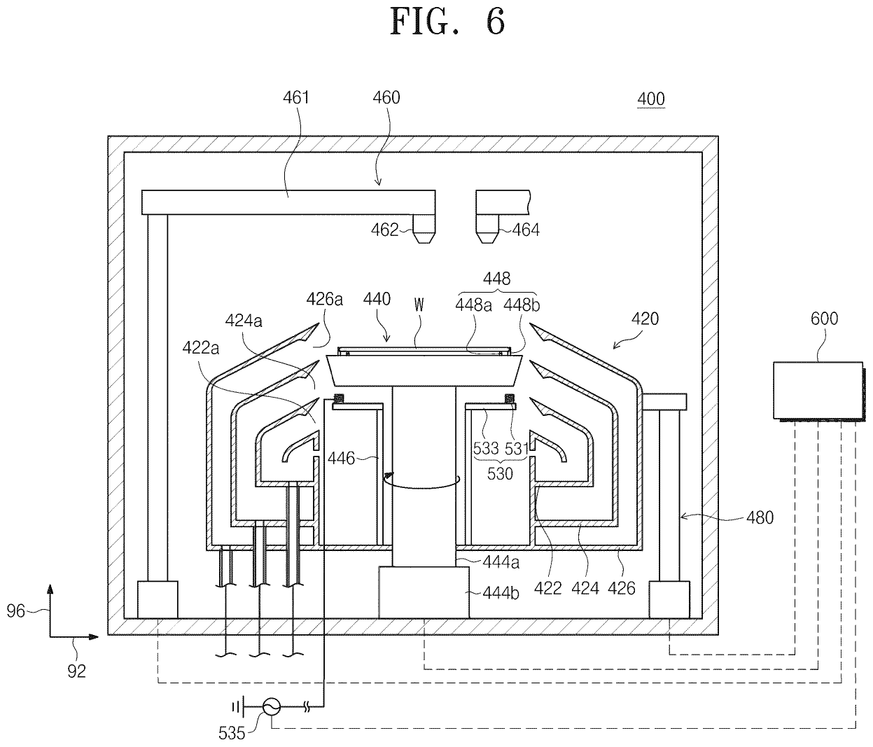

FIG. 5 is a diagram schematically illustrating another exemplary embodiment of the chuck pin of FIG. 4. Referring to FIG. 5, the chuck pin 448b may include a first chuck pin 448b-1 and a second chuck pin 448b-2. The insertion bodies 510 provided in the first chuck pin 448b-1 and the second chuck pin 448b-2 may be provided in different numbers. In one example, the number of insertion bodies 510 provided in the first chuck pin 448b-1 may be greater than the number of insertion bodies 510 provided in the second chuck pin 448b-1. The first chuck pin 448b-1 and the second chuck pin 448b-2 may be used interchangeably depending on the process of treating the substrate.

The magnet unit 530 inductively heats the insert 510. The magnet unit 530 may include a support 533 and a magnet 531. The magnet 531 may be positioned such that the magnetic field formed by the magnet 531 and the insertion body 510 may interfere with each other. In the following, the present invention has been described based on the case where the magnet 531 is located at a lower portion of the chuck pin 448b.

The magnet 531 may be located at a lower portion of the chuck pin 448b. The magnet 531 may be located on a lower portion of the support plate 442, and may be spaced apart from the support plate 442. The magnet 531 may be provided in a position corresponding to the chuck pin 448b when viewed from above. The magnets 531 may be provided in a plurality. The plurality of magnets 531 may be disposed along a circumferential direction of the support plate 442. In one example, the plurality of magnets 531 may be permanent magnets. In this case, the magnets 531 may have N and S poles, and the upper surfaces of magnets 531 adjacent to each other may be provided to have different poles.

The magnets 531 inductively heat the insertion body 510. The magnetic field formed by the magnet 531 generates a current within the insertion body 510, and the electrical energy of the generated current is converted to heat as it is dissipated by the internal resistance of the metal, causing the temperature of the insertion body 510 to rise.

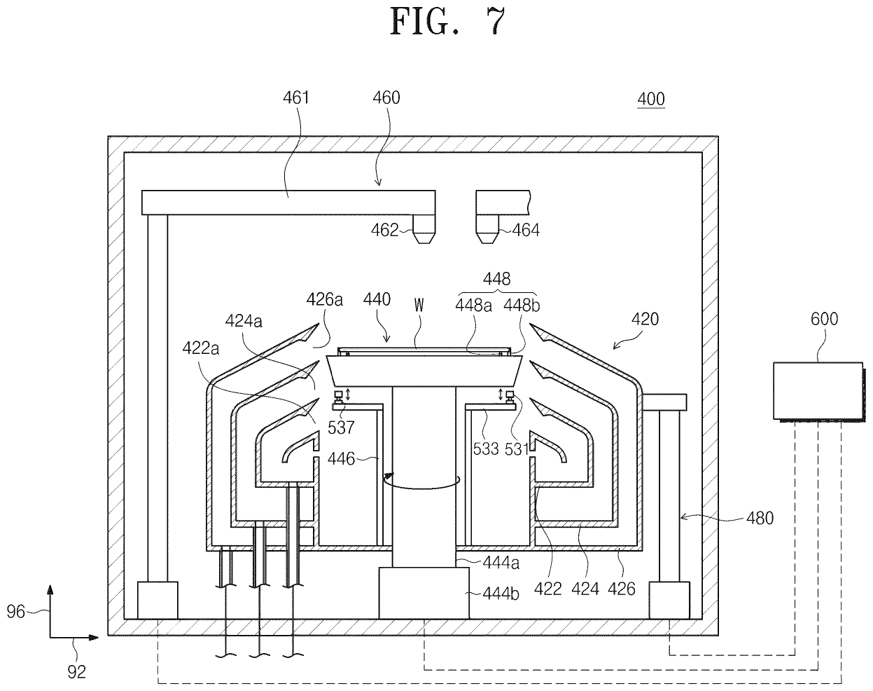

In the examples described above, the present invention has been described based on the case where the magnet 531 is a permanent magnet. However, without limitation, as illustrated in FIG. 6, the magnet 531 may be an electromagnet, the magnet unit 531 may further include a power source 535 that supplies power to the electromagnet, and the controller 600 may be provided to control the power source 535. The power source 535 may provide an alternating current to the electromagnet. In this case, the controller 600 may vary the power supplied to the electromagnet based on the treatment temperature of the substrate W.

The support 533 supports the magnet 531. The support 533 is fixedly coupled to the frame 446. The support 533 may have a shape extending outwardly from the frame 446. The support 533 may be coupled to an upper wall of the frame 446. Additionally, the support 533 may be coupled to a side wall of the frame 446. However, the present invention is not limited thereto and it is sufficient if the frame 446 is not provided and the support 533 is shaped to support the magnet 531 at the lower portion of the chuck pin 448b.

The controller 600 may include a Central Processing Unit (CPU), Read Only Memory (ROM), and Random Access Memory (RAM). The CPU executes desired processing, such as etching treatment according to various recipes stored in these storage areas. The recipe contains the device's control information for the process conditions. Meanwhile, the program or recipe representing the processing conditions may be stored in a non-transitory computer-readable medium. A non-transitory computer-readable medium means a medium that stores data on a semi-permanent basis and is readable by a computer, rather than a medium that stores data for a short period of time, such as a register, cache, memory, or the like. Specifically, the various applications or programs described above may be stored and provided on non-transitory readable media, such as CDs, DV Ds, hard disks, Blu-ray discs, USBs, memory cards, or ROMs.

Hereinafter, a substrate processing method according to an exemplary embodiment will be described. The substrate processing method described herein may be performed by the substrate processing apparatus described with reference to FIGS. 1 to 6. Accordingly, hereinafter, the substrate processing method by the exemplary embodiment will be described with reference to the reference numerals illustrated in FIGS. 1 to 5 without changes. Further, the substrate processing method described herein may be performed by the controller 600 controlling configurations included in the substrate processing apparatus described above.

In the exemplary embodiment, the substrate W is loaded onto the support plate 442, and the chuck pin 448b supports the substrate W at a side portion of the substrate W. The driver 444b applies rotational force to the drive shaft 444a to rotate the support plate 442, thereby rotating the substrate W. Then, the nozzle unit 460 supplies the treatment solution to the substrate W, and the substrate W is treated by the treatment solution. The substrate W is treated at a set temperature. The set temperature may be a temperature of the treatment solution, or it may be a set temperature of the heater 442a. In one example, the treatment solution may be a treatment solution of 200° C. or less. When the support plate 442 rotates, the chuck pin 448b also rotates along with the support plate 442. At this time, the insertion body 510 in the chuck pin 448b interferes with the magnetic field formed by the plurality of magnets 531 located at the bottom. Since the upper surfaces of the plurality of magnets 531 are arranged such that the N and S poles alternately and repeatedly appear, the direction of the magnetic field interfering with the insertion body 510 is continuously changing. Thus, a current is formed in the insertion body 510, and the direction of the current changes. The current dissipates electrical energy through resistance, which is converted to thermal energy. That is, the insertion body 510 is inductively heated. The chuck pin 448b is heated by the inductively heated insertion body 510, and the heated chuck pin 448b heats the treatment solution adjacent to the chuck pin 448b, which may improve the temperature uniformity of the treatment solution present on the substrate W.

Further, the substrate W may be treated by selectively installing the first chuck pin 448b-1 and the second chuck pin 448b-2 on the support plate 442. In one example, the first chuck pin 448b-1 may be installed when performing a first process and the second chuck pin 448b-2 may be installed when performing a second process. The first process may be a process in which the substrate is treated at a higher temperature than the second process. Since the higher the set temperature, the greater the temperature decrease in the edge region, the temperature uniformity may be improved by using the first chuck pin 448b-1 provided with more insertion bodies 510 to increase the induction heating effect.

Furthermore, when a substrate is treated by using the substrate processing apparatus of FIG. 6, temperature uniformity may be improved by adjusting the amount of power supplied by the power source 535 according to the set temperature at which the substrate is treated to adjust the degree to which the chuck pins 448b are inductively heated.

In the examples described above, the present invention has been described based on the case where the chuck pins are provided with only the first chuck pin 448b-1 and the second chuck pin 448b-2. However, the present invention is not limited thereto, and a plurality of chuck pins having a thickness or number of insertion bodies 510 different from the thickness or number of insertion bodies provided in the first chuck pin 448b-1 and the second chuck pin 448b-2 may be further included, and may be interchanged according to the process.

In the examples described above, the present invention has been described based on the case where the chuck pins are provided in different numbers in the insertion bodies 510 provided in the first chuck pin 448b-1 and the second chuck pin 448b-2. However, the present invention is not limited thereto, and the same number of insertion bodies 510 may be provided, and different thicknesses of insertion bodies 510 may be provided.

Further, in the examples described above, the present invention has been described based on the case where the magnet 531 is located on the lower portion of the chuck pin 448b. However, present invention is not limited thereto, and it is sufficient if the magnet 531 is provided at a location where interference occurs between the insertion boy 510 and the magnetic field formed by the magnet 531.

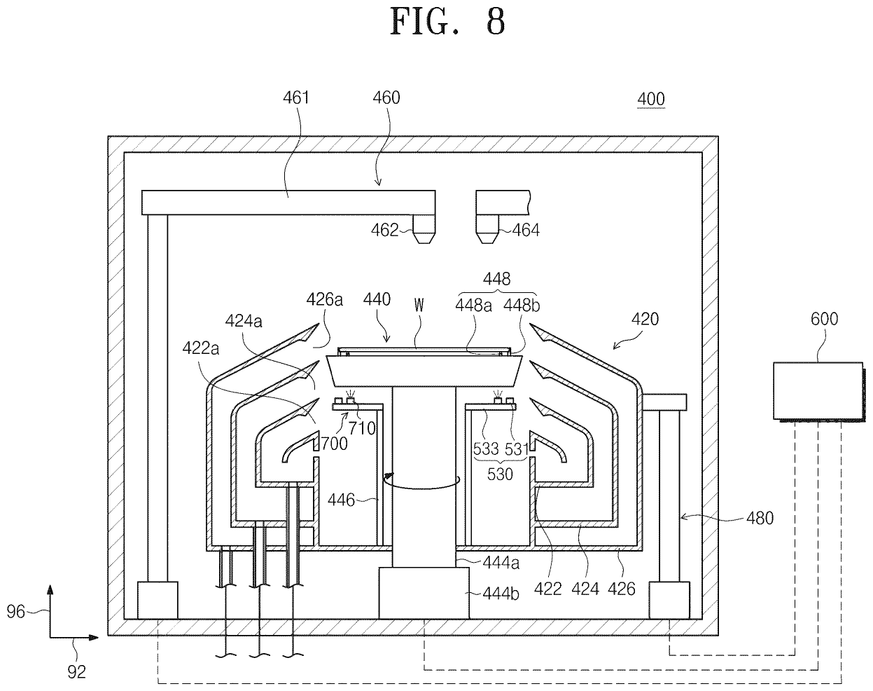

Furthermore, in the examples described above, the support 533 is fixed to the frame 446 and the magnet 531 is fixed to the support. However, the present invention is not limited thereto, and the support may be provided with a lifting part 537 for adjusting the height of the magnet 531 on the support, as illustrated in FIG. 7, and the magnet 531 may be provided to be moved up and down by the lifting part 537. In this case, by adjusting the height of the magnet 531, the interference between the insert 510 and the magnetic field may be adjusted to control the temperature of the insertion body 510 by induction heating. In one example, the lifting part 537 may be a motor.

Further, in the example described above, the present invention has been described based on the case where the support 533 is installed on the frame 446 and the magnet 531 is installed on the support 533. However, the present invention is not limited thereto, and it is also possible that the support 533 is not provided and a cleaning unit 700 including a cleaning nozzle 710 for cleaning a lower portion of the support plate 442 is installed on the frame 446, and the magnet 531 is provided to be installed on the cleaning unit 700, as illustrated in FIG. 8.

Further, in the example described above, the present invention has been described based on the case where the induction heating is adjusted by replacing the chuck pin 448b or adjusting the power source 535. However, the present invention is not limited thereto, and the induction heating may also be controlled by adjusting the rotational speed of the support plate 442.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

1. An apparatus of processing a substrate, the apparatus comprising:
a housing for providing a treatment space to treat a substrate;
a support unit positioned in the treatment space and for supporting the substrate;
a nozzle for supplying a treatment solution to the substrate supported on the support unit; and
a heating unit for heating an edge region of the substrate supported on the support unit,
wherein the support unit includes:
a support plate on which the substrate is placed;
a pin for supporting the substrate placed on the support plate; and
a drive unit for rotating the support plate, and
the heating unit includes:
an insertion body made of metal located within the pin; and
a magnet unit for heating the insertion body by an induction heating manner.

2. The apparatus of claim 1, wherein the pin is a chuck pin that supports a side portion of the substrate placed on the support plate.

3. The apparatus of claim 2, wherein the magnet unit is located at a lower portion of the chuck pin and provided to be spaced apart from the support plate.

4. The apparatus of claim 3, wherein the support unit includes a frame surrounding the drive unit,
and the frame is provided to be fixed in position with respect to rotation of the support unit, and
the magnet unit is installed on the frame.

5. The apparatus of claim 4,
the frame is provided with a cleaning unit for cleaning a lower portion of the support plate is provided at the frame,
wherein the magnet unit includes a plurality of magnets, and
the plurality of magnets is installed in the cleaning unit.

6. The apparatus of claim 2, wherein the magnet unit includes a plurality of magnets, and
the plurality of magnets is disposed while being spaced apart from each other along a circumferential direction of the support plate.

7. The apparatus of claim 6, wherein each of the plurality of magnets is provided with a top end and a bottom end having different polarities, and
the top ends of adjacent magnets of the plurality of magnets have different polarities.

8. The apparatus of claim 2, further comprising:
a controller for controlling the drive unit,
wherein the controller controls a rotation speed of the support plate according to a set temperature for treating the substrate.

9. The apparatus of claim 2, wherein the support unit includes:
an electromagnet;
a power source for providing the electromagnet with power.

10. The apparatus of claim 9, further comprising:
a controller for controlling the power source,
wherein the controller controls the power source so that set power is applied to the electromagnet according to a set temperature for treating the substrate.

11. The apparatus of claim 1, wherein the insertion body has a plate shape, and
the insertion bodies are provided in plurality to be stacked on top of each other.

12. The apparatus of claim 1, wherein the support unit includes a heater for heating the substrate supported by the support plate.

13. (canceled)

14. (canceled)

15. (canceled)

16. (canceled)

17. (canceled)

18. (canceled)

19. An apparatus of processing a substrate, the apparatus comprising:
a housing for providing a treatment space to treat a substrate;
a support unit positioned in the treatment space and supporting the substrate;
a nozzle for supplying a treatment solution to the substrate supported on the support unit; and
a heating unit for heating an edge region of the substrate supported on the support unit,
wherein the support unit includes:
a support plate on which the substrate is placed;
a chuck pin for supporting a side portion of the substrate placed on the support plate; and
a drive unit for rotating the support plate; and
a heater for heating the substrate supported by the support plate,
the heating unit includes:
an insertion body made of metal located within the chuck pin; and
a magnet unit located at a lower portion of the pin, and provided to be spaced apart from
the support plate,
the support unit further includes a frame surrounding the drive unit,
the magnet unit includes a plurality of magnets,
the plurality of magnets is spaced apart from each other along a circumferential direction of the support plate,
any one of the plurality of magnets has a different polarity from another magnet of the plurality of magnets, and
the plurality of magnets of different polarities is provided to be adjacent to each other.

20. The apparatus of claim 19, wherein the support unit further includes:
an electromagnet; and
a power source for supplying power to the electromagnet,
the apparatus further includes a controller for controlling the power source, and
the controller controls the power source according to a temperature for treating the substrate or a speed for rotating the substrate.
